(19) United States
(12) Patent Application Publication
(10) Pub. No.: US 2024/0405156 A1
(43) Pub. Date: Dec. 5, 2024

(54) ALTERNATING ELECTRIC FIELD-DRIVEN GALLIUM NITRIDE (GAN)-BASED NANO-LIGHT-EMITTING DIODE (NANOLED) STRUCTURE WITH ELECTRIC FIELD ENHANCEMENT EFFECT

(71) Applicant: Nanjing University, Nanjing (CN)

(72) Inventors: Tao TAO, Nanjing (CN); Rui ZHAO, Nanjing (CN); Ting ZHI, Nanjing (CN); Yu YAN, Nanjing (CN); Zili XIE, Nanjing (CN); Bin LIU, Nanjing (CN)

(73) Assignee: Nanjing University, Nanjing (CN)

(21) Appl. No.: 18/680,824

(22) Filed: May 31, 2024

(30) Foreign Application Priority Data
Jun. 1, 2023 (CN) 202310639955.0

(51) Int. Cl. H01L 33/08; H01L 33/00; H01L 33/02; H01L 33/06; H01L 33/12; H01L 33/24; H01L 33/32; H01L 33/42

(52) U.S. Cl. CPC H01L 33/08; H01L 33/007; H01L 33/025; H01L 33/06; H01L 33/12; H01L 33/24; H01L 33/32; H01L 33/42

(57) ABSTRACT

An alternating electric field-driven gallium nitride (GaN)-based nano-light-emitting diode (nanoLED) structure with an electric field enhancement effect is provided. The GaN-based nanoLED structure forms a nanopillar structure that runs through an indium tin oxide (ITO) layer, a p-type GaN layer, a multiple quantum well (MQW) active layer and an n-type GaN layer and reaches a GaN buffer layer; and the nanopillar structure has a cross-sectional area that is smallest at the MQW active layer and gradually increases towards two ends of a nanopillar, forming a pillar structure with a thin middle and two thick ends. The shape of the GaN-based nanopillar improves the electric field strength within the QW layer in the alternating electric field environment and increases the current density in the QW region of the nanopillar structure under current driving, forming strong electric field gain and current gain, thereby improving the luminous efficiency of the device.

### CROSS REFERENCE TO THE RELATED APPLICATIONS

This application is based upon and claims priority to Chinese Patent Application No. 202310639955.0, filed on Jun. 1, 2023, the entire contents of which are incorporated herein by reference.

### TECHNICAL FIELD

The present disclosure relates to an alternating electric field-driven gallium nitride (GaN)-based nano-light-emitting diode (nanoLED) structure with an electric field enhancement effect, and belongs to the technical field of wide bandgap semiconductor materials and light-emitting devices.

### BACKGROUND

In recent decades, optoelectronic devices have been widely studied and applied in many fields such as communications and storage, display and lighting, food safety, and new displays. GaN-based optoelectronic devices have the advantages of high luminous efficiency, energy conservation, environmental protection, small size, and long lifespan, presenting good development prospects. GaN materials have been extensively studied and used in optoelectronic devices such as light-emitting diodes (LEDs) and laser diodes (LDs). Despite the in-depth study on GaN-based LEDs, traditional LEDs generally operate under direct current (DC). This operating mode has a limitation, that is, as the pixel size decreases, the metal electrodes are hard to integrate into the LED device or form good ohmic contacts. In this context, a new type of LED driving technology, namely alternating electric field driving technology, has emerged and received widespread attention in the field where DC-driven nanoLEDs are limited.

Due to their unique advantages and potential application value, alternating electric field-driven LEDs have been widely studied and become a potential alternative to DC-driven LEDs. Compared to DC-driven light-emitting devices, alternating current (AC)-driven light-emitting devices have significant advantages in the field of nanoscale light-emitting devices. For example, the direction and frequency of the applied electric field can be changed to effectively prevent charge accumulation in the light-emitting device and improve the luminous efficiency, and the insulating dielectric layer in the AC-driven device can avoid non-radiative recombination of injected carriers to reduce heating. Alternating electric field-driven GaN-based LEDs can achieve non-contact driving of nano-display pixels, and alternating electric field driving is expected to replace DC driving as a new driving mode for ultra-high resolution displays. Therefore, it is highly desirable to explore AC-driven nanoLED structures with high gains.

### SUMMARY

An objective of the present disclosure is to provide an alternating electric field-driven gallium nitride (GaN)-based nano-light-emitting diode (nanoLED) structure with an electric field enhancement effect.

The present disclosure adopts the following technical solution.

An alternating electric field-driven GaN-based nanoLED structure with an electric field enhancement effect includes the following components in sequence from bottom to top:
a substrate;
a GaN buffer layer grown on the substrate;
an n-type GaN layer grown on the GaN buffer layer;
a multiple quantum well (MQW) active layer grown on the n-type GaN layer; and
a p-type GaN layer grown on the MQW active layer; and
the GaN-based nanoLED structure forms a nanopillar structure that runs through the p-type GaN layer, the MQW active layer and the n-type GaN layer and reaches the GaN buffer layer; a nanopillar has a diameter of 150-900 nm, a period of 300-1,000 nm, and a height of 400-2,000 nm; and the nanopillar structure has a cross-sectional area that is smallest at the MQW active layer and gradually increases towards two ends of a nanopillar, forming a pillar structure with a thin middle and two thick ends. Generally, the electric field distribution can be changed to achieve a gain as long as the cross-sectional area of the MQW active layer is smaller than the area of the p-type GaN layer/n-type GaN layer.

Preferably, the GaN-based nanoLED structure further includes an indium tin oxide (ITO) layer grown on the p-type GaN layer.

Preferably, the GaN-based nanoLED structure further includes an electrode layer below the substrate layer.

Preferably, the substrate is a silicon substrate or a sapphire substrate with a thickness of 300-500 μm.

Preferably, the GaN buffer layer is an undoped GaN buffer layer with a thickness of 1-5 μm.

Preferably, the n-type GaN layer has a doping concentration of 1-500×10¹⁷ cm⁻² and a thickness of 0.5-3 μm.

Preferably, the MQW active layer is a periodic structure of InGaN/GaN, with 3-10 periods; a content of In in an InGaN layer accounts for 0.02-0.25, and the InGaN layer has a thickness of 1-4 nm; and a GaN layer has a thickness of 5-18 nm.

Preferably, the p-type GaN layer has a doping concentration of 1-50×10¹⁷ cm⁻² and a thickness of 0.1-1 μm.

Preferably, the ITO layer has a thickness of 30-300 nm.

Preferably, the electrode layer is a double-layer structure of titanium (Ti) and gold (Au), with a Ti thickness of 2-40 nm and an Au thickness of 10-1,000 nm.

Preferably, the nanopillar has a diameter of 150-900 nm, a period of 300-1,000 nm, and a height of 400-2,000 nm.

In the present disclosure, the nanopillar is thinner on the multiple quantum well (MQW) layer and thicker on the P-type and N-type GaN layers, forming a structure with a thin middle and two thick ends. The shape of the GaN-based nanopillar improves the electric field strength within the QW layer in the alternating electric field environment and increases the current density in the QW region of the nanopillar structure under current driving, forming strong electric field gain and current gain, thereby improving the luminous efficiency of the device.

### BRIEF DESCRIPTION OF THE DRAWINGS

FIG. 1 is a schematic diagram of an alternating electric field-driven GaN-based nanoLED structure with an electric field enhancement effect according to the present disclosure;

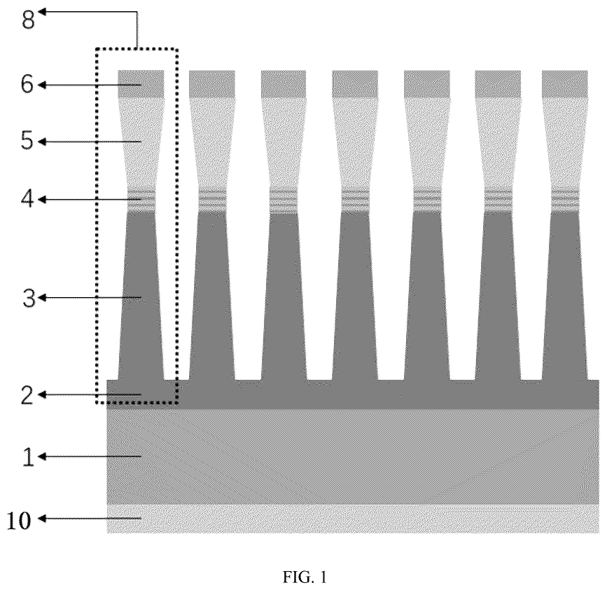

FIG. 2 is a structural diagram of a blue LED epitaxial wafer according to the present disclosure;

FIG. 3 is a schematic diagram of a structure formed by step (2) according to Embodiment 1;

FIG. 4 is a schematic diagram of a structure formed by step (3) according to Embodiment 1;

FIG. 5 is a schematic diagram of a structure formed by step (4) according to Embodiment 1;

FIG. 6 is a schematic diagram of a structure formed by step (5) according to Embodiment 1;

FIG. 7 is a schematic diagram of a structure formed by step (6) according to Embodiment 1;

FIG. 8 is a schematic diagram of a structure formed by step (7) according to Embodiment 1;

FIG. 9 is a schematic diagram of a structure formed by step (8) according to Embodiment 1;

FIG. 10 is a schematic diagram of a structure formed by step (9) according to Embodiment 1;

FIG. 11 is a schematic diagram of a structure formed by step (10) according to Embodiment 1;

FIG. 12 is a scannogram, acquired by a transmission electron microscope (TEM), of the alternating electric field-driven GaN-based nanoLED structure with an electric field enhancement effect according to Embodiment 1;

FIG. 13 is a schematic diagram showing a relationship between a current, a power, and a QW diameter of the alternating electric field-driven GaN-based nanoLED structure with an electric field enhancement effect according to Embodiment 1;

FIG. 14 is a schematic diagram showing a luminance of a GaN-based nanoLED structure according to Comparative Example 1; and

FIG. 15 is a schematic diagram showing a luminance of an alternating electric field-driven GaN-based nanoLED structure with an electric field enhancement effect according to Embodiment 1.

### REFERENCE NUMERALS

1. substrate; 2. GaN buffer layer; 3. N—GaN layer; 4. MQW layer; 5. P—GaN layer; 6. ITO layer; 7. SiO₂ mask layer; 8. nanopillar; 9. photoresist layer; and 10. electrode.

The specific embodiments of the present disclosure will be further described with reference to the drawings.

### DETAILED DESCRIPTION OF THE EMBODIMENTS

The technical solutions in the embodiments of the present disclosure will be described clearly and completely with reference to the drawings in the embodiments of the present disclosure. Apparently, the described embodiments are merely a part rather than all of the embodiments of the present disclosure. All other embodiments obtained by a person of ordinary skill in the art based on the embodiments of the present disclosure without creative efforts shall fall within the protection scope of the present disclosure.

### Embodiment 1: Alternating Electric Field-Driven GaN-Based NanoLED Structure with Electric Field Enhancement Effect

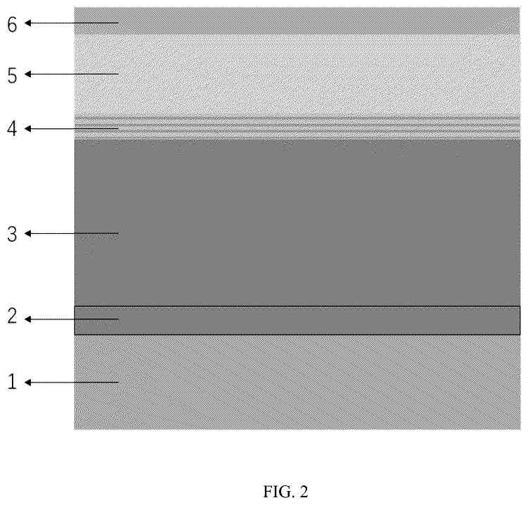

In this embodiment, FIG. 2 shows an epitaxial wafer for a substrate material, which is a standard blue LED epitaxial wafer with a pn structure. The epitaxial wafer includes silicon substrate 1, GaN buffer layer 2 grown on the silicon substrate, n-type GaN layer 3 grown on the GaN buffer layer, QW active layer 4 grown on the n-type GaN layer, p-type GaN layer 5 grown on the QW active layer, and ITO layer 6 grown on the p-type GaN layer. The epitaxial wafer can also be a blue LED epitaxial wafer that does not include the ITO layer.

Specifically, the alternating electric field-driven GaN-based LED structure with a high current gain is prepared as follows.

(1) The blue LED epitaxial wafer is cleaned by conducting ultrasonic cleaning in an acetone solution for 10-15 min, conducting a water bath for 10-15 min in an ethanol solution, rinsing with deionized water, and blow-drying.

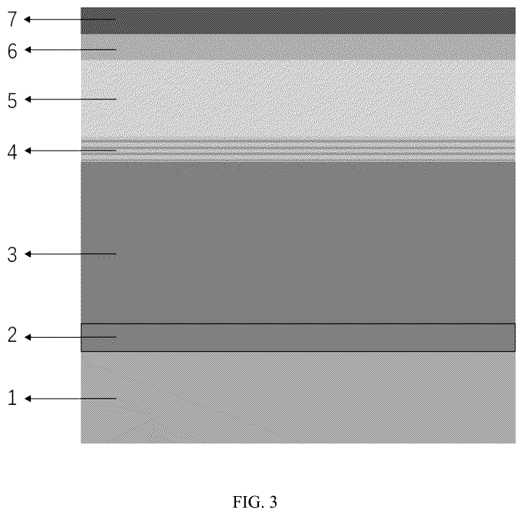

(2) As shown in FIG. 3, 200 nm thick SiO₂ mask layer 7 is deposited on the InxGa1−xN/GaN QW blue LED epitaxial wafer by plasma enhanced chemical vapor deposition (PECVD). SiO₂ is grown by PECVD by: introducing a 5% SiH₄/N₂ mixture and N₂O into a reaction chamber at flow rates of 400 sccm and 500 sccm respectively, and conducting a reaction of SiH₄+O→SiO₂ (+H₂O) at a pressure of 850 mTorr, a power of 50 W, and a temperature of 250° C. to deposit SiO₂ on a surface of the epitaxial wafer for 1 min and 20 s.

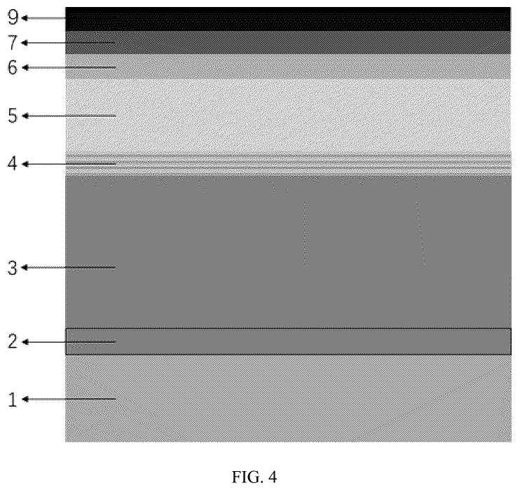

(3) As shown in FIG. 4, photoresist (AZ5214) layer 9 is spin-coated on the SiO₂ mask layer 7 by a spin-coater. When a speed of the spin-coater is 600 rpm, spin-coating is conducted for 9 s. When the speed of the spin coater is 4,000 rpm, the spin-coating is conducted for 40 s. After the spin-coating, baking is conducted at 100° C. for 1 min by a hot stage.

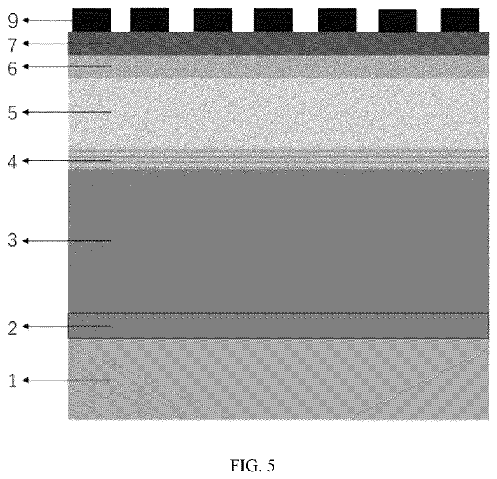

(4) As shown in FIG. 5, a periodic arrangement pattern is transferred to the photoresist layer 9. Hard contact exposure is conducted for 2.5 s by a SUSS UV lithography machine. Then development is conducted in a developer for 40 s. rinsing with deionized water and blow-drying are conducted.

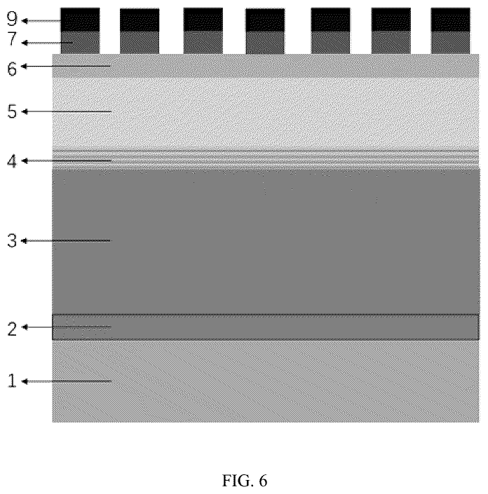

(5) As shown in FIG. 6, the pattern is transferred from the photoresist layer 9 to the SiO₂ mask layer 7. SiO₂ is etched by a reactive ion etching (RIE) device. CF₄ is introduced. The conditions include: CF₄ flow rate 30 sccm, reaction pressure in the chamber 4 Pa, RF power 120 W, and time 6 min.

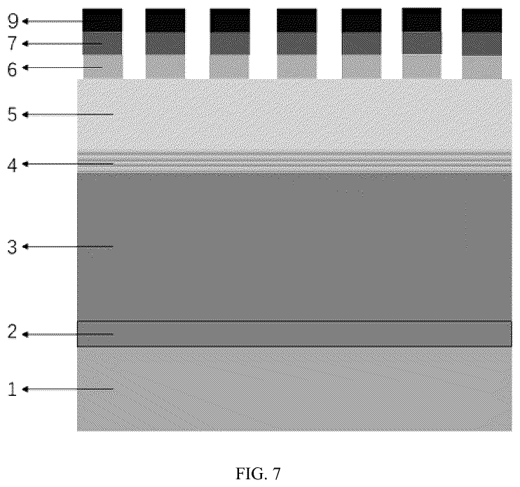

(6) As shown in FIG. 7, an excess of the ITO layer 6 is removed. Wet etching is conducted by an ITO corrosion solution, and a 50° C. water bath is conducted. The wet etching time is strictly controlled within 3 min.

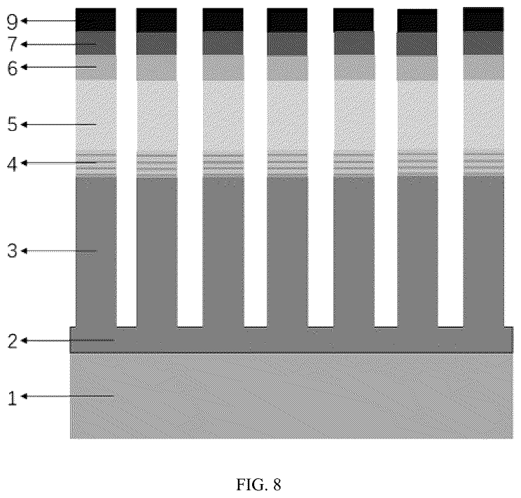

(7) As shown in FIG. 8, Cl₂ and BCl₃ are introduced into the reaction chamber, and the photoresist layer 9 and the SiO₂ mask layer 7 are used as a mask anisotropic etching on the p-type GaN layer 5, the QW layer 4, and the n-type GaN layer 3 by an inductively coupled plasma (ICP) etching device until a periodic and isolated nanoscale pillar mesa structure is formed on the n-type GaN buffer layer 2. Nanopillar 8 includes the n-type GaN buffer layer 2, the n-type GaN layer 3, the QW layer 4, the p-type GaN layer 5, and the ITO layer 6. The etching conditions include: RF power 100 W; ICP power 300 W, Cl₂ flow rate 48 sccm, BCl₃ flow rate 6 sccm, air pressure 10 mTorr, and reaction time 1 min and 15 s.

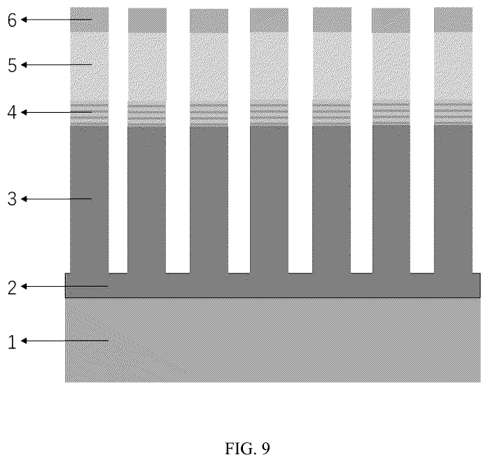

(8) As shown in FIG. 9, the residual photoresist layer 9 is removed by ultrasonic cleaning with acetone, ethanol, and deionized water in sequence for 5 min. After the residual photoresist is removed, the following operations are conducted: soaking in a buffered oxide etch (BOE) solution for 3 min, cleaning with deionized water, and blow-drying to remove the SiO₂ mask layer 7.

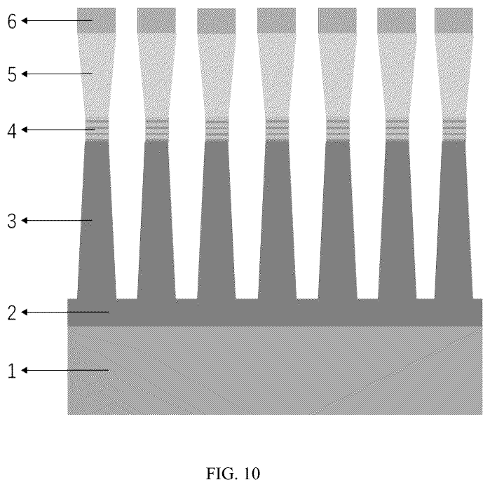

(9) As shown in FIG. 10, a side wall of the nanopillar 8 is modified by wet etching to form a nanopillar structure with a thin middle and two thick ends. The wet corrosion is conducted by a KOH solution diluted in a 1:1 volume ratio or a NaOH solution diluted in a 1:1 volume ratio, and an 80° C. water bath is conducted for 10 min. Then the etched sidewall is repaired by a H₃PO₄ solution diluted in a 1:1 volume ratio, and an 80° C. water bath is conducted for 60 min. The KOH solution diluted in a 1:1 volume ratio refers to a saturated solution of water and the KOH solution mixed in a 1:1 volume ratio, applicable to other solutions.

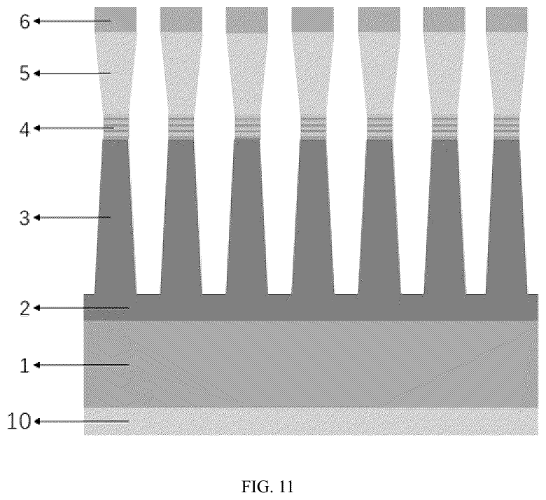

(10) As shown in FIG. 11, single-ended electrode 10 is prepared. 10 nm thick nickel (Ni) and 50 nm thick gold (Au) are sequentially deposited on the substrate 1 by an electron beam evaporator (EBE).

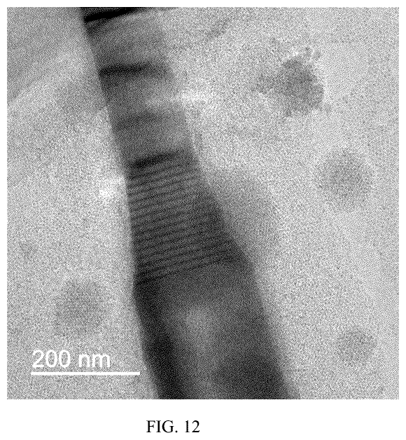

The GaN-based nanoLED structure with an electric field enhancement effect was captured by a transmission electron microscope (TEM (FEI Tecnai F20 TEM)), as shown in FIG. 12.

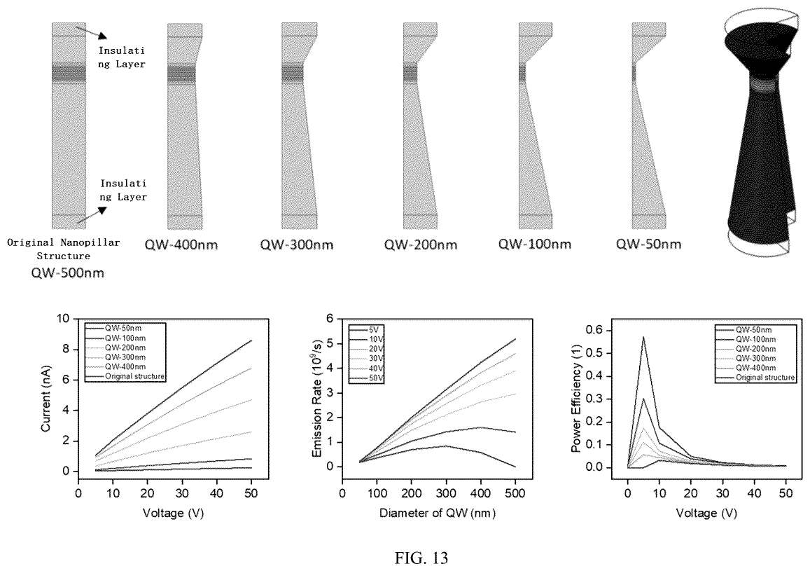

The relationship between the current, power, and efficiency of the GaN-based nanoLED structure with an electric field enhancement effect and a QW diameter was calculated by FDTD simulation software, as shown in FIG. 13.

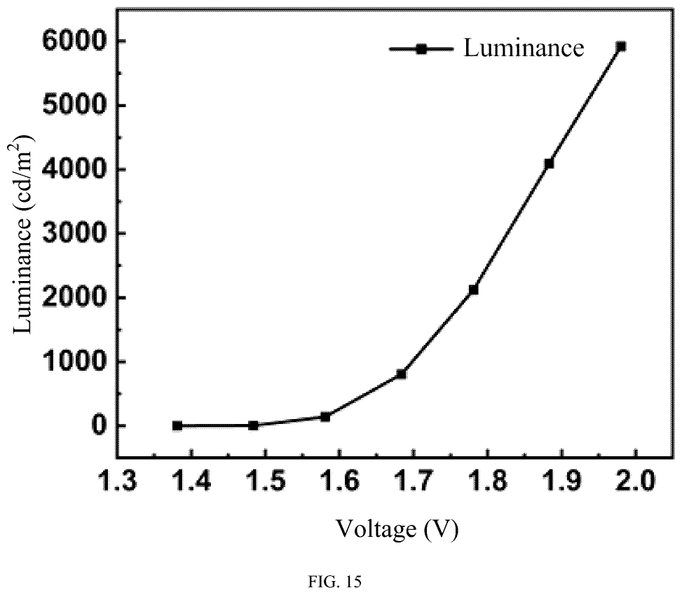

The luminous intensity of the GaN-based nanoLED structure with an electric field enhancement effect under different voltages was tested by an electric injection method, as shown in FIG. 15.

### Embodiment 2: Alternating Electric Field-Driven GaN-Based NanoLED Structure with Electric Field Enhancement Effect

In this embodiment, an epitaxial wafer for a substrate material is a standard blue LED epitaxial wafer with a pn structure. The epitaxial wafer includes a sapphire substrate, a GaN buffer layer grown on the silicon substrate, an n-type GaN layer grown on the GaN buffer layer, a QW active layer grown on the n-type GaN layer, a p-type GaN layer grown on the QW active layer, and an ITO layer grown on the p-type GaN layer.

Specifically, the alternating electric field-driven GaN-based LED structure with a high current gain is prepared as follows.

(1) The blue LED epitaxial wafer is cleaned by conducting ultrasonic cleaning in an acetone solution for 10-15 min, conducting a water bath for 10-15 min in an ethanol solution, rinsing with deionized water, and blow-drying.

(2) 200 nm thick SiO₂ mask layer is deposited on the InxGa1−xN/GaN QW blue LED epitaxial wafer by plasma enhanced chemical vapor deposition (PECVD). SiO₂ is grown by PECVD by: introducing a 5% SiH₄/N₂ mixture and N₂O into a reaction chamber at flow rates of 100 sccm and 450 sccm respectively, and conducting a reaction of SiH++O→SiO₂ (+H₂O) at a pressure of 300 m Torr, a power of 10 W, and a temperature of 350° C. to deposit SiO₂ on a surface of the epitaxial wafer for 9 min and 30 s.

(3) A photoresist (AZ6130) layer is spin-coated on the SiO₂ mask layer by a spin-coater. When a speed of the spin-coater is 500 rpm, spin-coating is conducted for 6 s. When the speed of the spin coater is 2,000 rpm, the spin-coating is conducted for 40 s. After the spin-coating, baking is conducted at 110° C. for 4 min by a hot stage.

(4) A periodic arrangement pattern is transferred to the photoresist layer Hard contact exposure is conducted for 2 s by a SUSS UV lithography machine. Then development is conducted in a developer for 40 s. rinsing with deionized water and blow-drying are conducted.

(5) The pattern is transferred from the photoresist layer to the SiO₂ mask layer. The SiO₂ mask layer is etched by a RIE device. CF₄ is introduced. The conditions include: CF₄ flow rate 30 sccm, reaction pressure in the chamber 4 Pa, RF power 120 W, and time 6 min.

(6) An excess of the ITO layer is removed. Wet etching is conducted by an ITO corrosion solution, and a 50° C. water bath is conducted. The wet etching time is strictly controlled within 3 min.

(7) Cl₂ and BCl₃ are introduced into the reaction chamber, and the photoresist layer 9 and the SiO₂ mask layer are used as a mask anisotropic etching on the p-type GaN layer, the QW layer, and the n-type GaN layer by an ICP etching device until a periodic and isolated nanoscale pillar mesa structure is formed on the n-type GaN buffer layer. The etching conditions include: RF power 100 W; ICP power 300 W, Cl₂ flow rate 48 sccm, BCl₃ flow rate 6 sccm, air pressure 10 m Torr, and reaction time 2 min.

(8) The residual photoresist layer is removed by ultrasonic cleaning with acetone, ethanol, and deionized water in sequence for 5 min. After the residual photoresist is removed, the following operations are conducted: soaking in a BOE solution for 3 min, cleaning with deionized water, and blow-drying to remove the SiO₂ mask layer.

(9) A side wall of the nanopillar is modified by wet etching to form a nanopillar structure with a thin middle and two thick ends. The wet corrosion is conducted by a KOH solution diluted in a 1:1 volume ratio or a NaOH solution diluted in a 1:1 volume ratio, and an 80° C. water bath is conducted for 8 min. Then the etched sidewall is repaired by a diluted H₃PO₄ solution, and an 80° C. water bath is conducted for 45 min.

(10) A single-ended electrode is prepared. 10 nm thick Ni and 50 nm thick Au are sequentially deposited on the substrate by an EBE.

### Comparative Example 1: Alternating Electric Field-Driven GaN-Based NanoLED Structure without Electric Field Enhancement

In the comparative example, an epitaxial wafer for a substrate material is a standard blue LED epitaxial wafer with a pn structure. The epitaxial wafer includes a sapphire substrate, a GaN buffer layer grown on the silicon substrate, an n-type GaN layer grown on the GaN buffer layer, a QW active layer grown on the n-type GaN layer, a p-type GaN layer grown on the QW active layer, and an ITO layer grown on the p-type GaN layer.

A specific preparation method of the comparative example is as follows:
(1) The blue LED epitaxial wafer is cleaned by conducting ultrasonic cleaning in an acetone solution for 10-15 min, conducting a water bath for 10-15 min in an ethanol solution, rinsing with deionized water, and blow-drying.

(2) 200 nm thick SiO₂ mask layer is deposited on the InxGa1−xN/GaN QW blue LED epitaxial wafer by plasma enhanced chemical vapor deposition (PECVD). SiO₂ is grown by PECVD by: introducing a 5% SiH₄/N₂ mixture and N₂O into a reaction chamber at flow rates of 100 sccm and 450 sccm respectively, and conducting a reaction of SiH++O→SiO₂ (+H₂O) at a pressure of 300 m Torr, a power of 10 W, and a temperature of 350° C. to deposit SiO₂ on a surface of the epitaxial wafer for 9 min and 30 s.

(3) A photoresist (AZ6130) layer is spin-coated on the SiO₂ mask layer by a spin-coater. When a speed of the spin-coater is 500 rpm, spin-coating is conducted for 6 s. When the speed of the spin coater is 2,000 rpm, the spin-coating is conducted for 40 s. After the spin-coating, baking is conducted at 110° C. for 4 min by a hot stage.

(4) A periodic arrangement pattern is transferred to the photoresist layer Hard contact exposure is conducted for 2 s by a SUSS UV lithography machine. Then development is conducted in a developer for 40 s. rinsing with deionized water and blow-drying are conducted.

(5) The pattern is transferred from the photoresist layer to the SiO₂ mask layer. The SiO₂ mask layer is etched by a RIE device. CF₄ is introduced. The conditions include: CF₄ flow rate 30 sccm, reaction pressure in the chamber 4 Pa, RF power 120 W, and time 6 min.

(6) An excess of the ITO layer is removed. Wet etching is conducted by an ITO corrosion solution, and a 50° C. water bath is conducted. The wet etching time is strictly controlled within 3 min.

(7) Cl₂ and BCl₃ are introduced into the reaction chamber, and the photoresist layer 8 and the SiO₂ mask layer are used as a mask anisotropic etching on the p-type GaN layer, the QW layer, and the n-type GaN layer by an ICP etching device until a periodic and isolated nanoscale pillar mesa structure is formed on the n-type GaN buffer layer. The etching conditions include: RF power 100 W; ICP power 300 W, Cl₂ flow rate 48 sccm, BCl₃ flow rate 6 sccm, air pressure 10 mTorr, and reaction time 2 min.

(8) The residual photoresist layer is removed by ultrasonic cleaning with acetone, ethanol, and deionized water in sequence for 5 min. After the residual photoresist is removed, the following operations are conducted: soaking in a BOE solution for 3 min, cleaning with deionized water, and blow-drying to remove the SiO₂ mask layer.

(9) A single-ended electrode is prepared. 10 nm thick Ni and 50 nm thick Au are sequentially deposited on the substrate by an EBE.

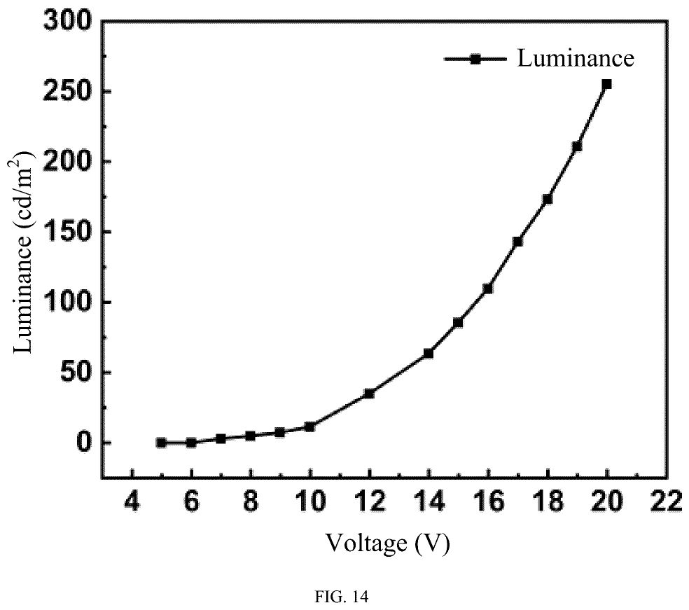

The luminous intensity of the GaN-based nanoLED structure without electric field enhancement in the comparative example under different voltages was tested by an electric injection method, as shown in FIG. 14.

The above embodiments are preferred implementations of the present disclosure. However, the implementations of the present disclosure are not limited by the above embodiments. Any change, modification, substitution, combination, and simplification made without departing from the spiritual essence and principle of the present disclosure should be an equivalent replacement manner, and all are included in the protection scope of the present disclosure.

1. An alternating electric field-driven gallium nitride (GaN)-based nano-light-emitting diode (nanoLED) structure with an electric field enhancement effect, comprising the following components in sequence from bottom to top:
a substrate;
a GaN buffer layer grown on the substrate;
an n-type GaN layer grown on the GaN buffer layer;
a multiple quantum well (MQW) active layer grown on the n-type GaN layer; and
a p-type GaN layer grown on the MQW active layer;
wherein the alternating electric field-driven GaN-based nanoLED structure forms a nanopillar structure, wherein the nanopillar structure runs through the p-type GaN layer, the MQW active layer and the n-type GaN layer and reaches the GaN buffer layer; and the nanopillar structure has a cross-sectional area that is smallest at the MQW active layer and gradually increases towards two ends of a nanopillar, forming a pillar structure with a thin middle and two thick ends.

2. The alternating electric field-driven GaN-based nanoLED structure according to claim 1, further comprising an indium tin oxide (ITO) layer, wherein the ITO layer is grown on the p-type GaN layer and has a thickness of 30-300 nm.

3. The alternating electric field-driven GaN-based nanoLED structure according to claim 1, further comprising an electrode layer, wherein the electrode layer is located below the substrate.

4. The alternating electric field-driven GaN-based nanoLED structure according to claim 1, wherein the substrate is a silicon substrate or a sapphire substrate with a thickness of 300-500 μm.

5. The alternating electric field-driven GaN-based nanoLED structure according to claim 1, wherein the GaN buffer layer is an undoped GaN buffer layer with a thickness of 1-5 μm.

6. The alternating electric field-driven GaN-based nanoLED structure according to claim 1, wherein the n-type GaN layer has a doping concentration of 1-500×10¹⁷ cm⁻² and a thickness of 0.5-3 μm.

7. The alternating electric field-driven GaN-based nanoLED structure according to claim 1, wherein the MQW active layer is a periodic structure of InGaN/GaN, with 3-10 periods; a content of In in an InGaN layer accounts for 0.02-0.25, and the InGaN layer has a thickness of 1-4 nm; and a GaN layer has a thickness of 5-18 nm.

8. The alternating electric field-driven GaN-based nanoLED structure according to claim 1, wherein the p-type GaN layer has a doping concentration of 1-50×10¹⁷ cm⁻² and a thickness of 0.1-1 μm.

9. The alternating electric field-driven GaN-based nanoLED structure according to claim 1, wherein the nanopillar has a diameter of 150-900 nm, a period of 300-1,000 nm, and a height of 400-2,000 nm.

10. The alternating electric field-driven GaN-based nanoLED structure according to claim 1, wherein the electrode layer is a double-layer structure of titanium (Ti) and gold (Au), with a Ti thickness of 2-40 nm and an Au thickness of 10-1,000 nm.

11. The alternating electric field-driven GaN-based nanoLED structure according to claim 2, wherein the substrate is a silicon substrate or a sapphire substrate with a thickness of 300-500 μm.

12. The alternating electric field-driven GaN-based nanoLED structure according to claim 3, wherein the substrate is a silicon substrate or a sapphire substrate with a thickness of 300-500 μm.

13. The alternating electric field-driven GaN-based nanoLED structure according to claim 2, wherein the GaN buffer layer is an undoped GaN buffer layer with a thickness of 1-5 μm.

14. The alternating electric field-driven GaN-based nanoLED structure according to claim 3, wherein the GaN buffer layer is an undoped GaN buffer layer with a thickness of 1-5 μm.

15. The alternating electric field-driven GaN-based nanoLED structure according to claim 2, wherein the n-type GaN layer has a doping concentration of 1-500×10¹⁷ cm⁻² and a thickness of 0.5-3 μm.

16. The alternating electric field-driven GaN-based nanoLED structure according to claim 3, wherein the n-type GaN layer has a doping concentration of 1-500×10¹⁷ cm⁻² and a thickness of 0.5-3 μm.

17. The alternating electric field-driven GaN-based nanoLED structure according to claim 2, wherein the MQW active layer is a periodic structure of InGaN/GaN, with 3-10 periods; a content of In in an InGaN layer accounts for 0.02-0.25, and the InGaN layer has a thickness of 1-4 nm; and a GaN layer has a thickness of 5-18 nm.

18. The alternating electric field-driven GaN-based nanoLED structure according to claim 3, wherein the MQW active layer is a periodic structure of InGaN/GaN, with 3-10 periods; a content of In in an InGaN layer accounts for 0.02-0.25, and the InGaN layer has a thickness of 1-4 nm; and a GaN layer has a thickness of 5-18 nm.

19. The alternating electric field-driven GaN-based nanoLED structure according to claim 2, wherein the p-type GaN layer has a doping concentration of 1-50×10¹⁷ cm⁻² and a thickness of 0.1-1 μm.

20. The alternating electric field-driven GaN-based nanoLED structure according to claim 3, wherein the p-type GaN layer has a doping concentration of 1-50×10¹⁷ cm⁻² and a thickness of 0.1-1 μm.
